(19) United States
(12) Patent Application Publication
(10) Pub. No.: US 2019/0364683 A1
(43) Pub. Date: Nov. 28, 2019

(54) COVER FILM

(71) Applicant: GUNZE LIMITED, Ayabe-shi (JP)

(72) Inventors: Keisuke MATSUBARA, Moriyama-shi (JP); Takuya IKEDA, Moriyama-shi (JP)

(21) Appl. No.: 16/355,536

(22) Filed: Mar. 15, 2019

(30) Foreign Application Priority Data
May 28, 2018 (JP) 2018-101744
Jun. 28, 2018 (JP) 2018-123213

(51) Int. Cl. H05K 5/03

(52) U.S. Cl. CPC H05K 5/03; H05K 5/0017

(57) ABSTRACT

The present invention provides a cover film for a bending display, and the cover film includes a transparent base film and a hard coat layer formed on at least one surface of the transparent base film, in which the hard coat layer has a thickness of 23 μm or less, and an end surface of the hard coat layer has a line roughness of 2.5 μm or less.

### TECHNICAL FIELD

The present invention relates to a cover film and a method for manufacturing the same.

### BACKGROUND ART

In recent years, various cover films for protecting surfaces of displays of smartphones and the like have been proposed. For example, JP 2003-292828A proposes a cover film having a film base material and a hard coat layer formed on the surface of the film base material.

JP 2003-292828A is an example of related art.

### SUMMARY OF THE INVENTION

Incidentally, in recent years, bending displays whose surfaces are bent (or curved) have been proposed. With such a display, a cover film disposed on the surface is also bent, and thus the cover film is required to have bending resistance. That is, when a cover film is bent, in particular, it is necessary that a crack does not appear in a hard coat layer. The present invention was made to solve the above-described problem, and an object of the present invention is to provide a cover film for a bending display, by which bending resistance can be increased.

Aspect 1. A cover film for a bending display, including:

a transparent base film; and

a hard coat layer formed on at least one surface of the transparent base film,

in which the hard coat layer has a thickness of 23 μm or less, and an end surface of the hard coat layer has a line roughness

Ra of 2.5 μm or less.

Aspect 2. The cover film according to Aspect 1,

in which the end surface is cut using a laser.

Aspect 3. The cover film according to Aspect 1 or 2,

in which the cover film has a surface pencil hardness of 3H or more.

Aspect 4. A method for manufacturing a cover film, including:

forming a cover film by stacking a hard coat layer having a thickness of 23 μm or less on a transparent base film;

disposing a protective film on the hard coat layer; and

cutting the cover film using a laser,

in which an end surface of the hard coat layer has a line roughness Ra of 2.5 μm or less.

Aspect 5. The method for manufacturing a cover film according to Aspect 4,

in which the laser has a cutting speed of 50 to 600 mm/sec.

The cover film according to the present invention makes it possible to increase bending resistance.

### BRIEF DESCRIPTION OF THE DRAWINGS

FIG. 1A is a plan view of a cover film illustrating a bending direction and line roughness.

FIG. 1B is a side view of FIG. 1A.

FIG. 2 is a diagram illustrating measurement of burrs.

### EMBODIMENTS OF THE INVENTION

Hereinafter, one embodiment of a cover film according to the present invention will be described. The cover film according to the present invention includes a transparent base film and a hard coat layer stacked on at least one surface of this base film. That is, the hard coat layer may be stacked on both surfaces of the base film. Hereinafter, each member will be described in detail. Note that numerical values connected using “-” refer to a numerical range including numerical values written in front of and after “-” as the lower limit and the upper limit. Also, if a plurality of lower limits and a plurality of upper limits are written separately, any lower limit and any upper limit may be selected and connected using “-”.

1. Base Film

Abase film according to the present invention can be made of various transparent materials, and can be made of cellulose acylates, cycloolefin polymers, polycarbonates, acrylate-based polymers, polyesters, polyimides, and the like, for example. In particular, polyimide is preferable because polyimide is strong against bending and is not likely to be creased even if a polyimide film is bent. Also, various additives can be added to this base film as needed. For example, various additives such as a plasticizer, an antistatic agent, and an ultraviolet absorbing agent may be added.

The base film preferably has a thickness of 25 μm or more and 300 μm or less, and more preferably has a thickness of 75 μm or more and 250 μm or less, for example. If the thickness is less than 25 μm, sufficient scratch resistance of the surface of the hard coat layer cannot be obtained, and if the thickness is larger than 300 μm, it is difficult to obtain sufficient bending durability.

The base film preferably has a hardness of 200 to 600 N/mm², more preferably has a hardness of 250 to 500 N/mm², and more preferably has a hardness of 300 to 450 N/mm², in a Martens hardness test. Accordingly, the scratch resistance is increased.

The Martens hardness can be measured using a Dynamic Ultra Micro Hardness Tester DUH-211 (SHIMADZU CORPORATION). A measurement can be made using a triangular pyramidal indenter with an edge angle of 115 degrees as an indenter under conditions where the indentation depth is 0.25 μm and the load speed is 0.15 mN/sec. A specific Martens hardness is a value calculated using an equation below.

Martens hardness [N/mm²]=Load [μN]/(24.5×(maximum depth hmax (μm)²)

2. Hard Coat Layer

Next, a hard coat layer will be described. The hard coat layer is obtained by curing a resin composition for forming a hard coat layer containing an ionizing radiation curable resin, a photopolymerization initiator, and the like. Also, an additive, which will be described later, can be added to this composition as needed.

2-1. Ionizing Radiation Curable Resin

An ionizing radiation curable resin includes a compound having radical polymerizability that, in response to ionizing radiation (ultraviolet rays or electron rays), undergoes polymerization or undergoes a crosslinking reaction, and the ionizing radiation curable resin may be a compound including at least one or more ethylenically unsaturated bonds in a structural unit or a mixture thereof.

Examples of a monofunctional compound including one unsaturated bond include 2-hydroxyethyl (meth)acrylate, 2-hydroxylpropyl (meth)acrylate, n-butyl (meth)acrylate, glycidyl (meth)acrylate, and cyclohexyl (meth)acrylate.

Examples of a bifunctional compound that includes two unsaturated bonds include di(meth)acrylates such as ethylene glycol di(meth)acrylate, diethylene glycol di(meth)acrylate, butanediol di(meth)acrylate, hexanediol di(meth)acrylate, nonanediol di(meth)acrylate, ethoxylated hexanediol di(meth)acrylate, propoxylated hexanediol di(meth)acrylate, diethylene glycol di(meth)acrylate, polyethylene glycol di(meth)acrylate, tripropylene glycol di(meth)acrylate, polypropylene glycol di(meth)acrylate, neopentyl glycol di(meth)acrylate, ethoxylated neopentyl glycol di(meth)acrylate, tripropylene glycol di(meth)acrylate, and hydroxypivalic acid neopentyl glycol di(meth)acrylate.

Also, examples of a polyfunctional compound that includes three or more unsaturated bonds include tri(meth)acrylates such as trimethylolpropane tri(meth)acrylate, ethoxylated trimethylolpropane tri(meth)acrylate, propoxylated trimethylolpropane tri(meth)acrylate, tris(2-hydroxyethyl)isocyanurate tri(meth)acrylate, and glycerin tri(meth)acrylate, trifunctional (meth)acrylate compounds such as pentaerythritol tri(meth)acrylate, dipentaerythritol tri(meth)acrylate, and ditrimethylolpropane tri(meth)acrylate, polyfunctional (meth)acrylate compounds having three or more functional groups, such as pentaerythritol tetra(meth)acrylate, ditrimethylolpropane tetra(meth)acrylate, dipentaerythritol tetra(meth)acrylate, dipentaerythritol penta(meth)acrylate, ditrimethylolpropane penta(meth)acrylate, dipentaerythritol hexa(meth)acrylate, and ditrimethylolpropane hexa(meth)acrylate, and (meth)acrylate compounds such as polyfunctional (meth)acrylate compounds obtained by substituting a portion of these (meth)acrylates with an alkyl group or s-caprolactone.

Also, a urethane-based resin can be mixed in the above-described (meth)acrylate compounds. Urethane (meth)acrylate-based resins can be used as the urethane-based resin, for example. Specifically, for example, a pentaerythritol triacrylate hexamethylene diisocyanate urethane prepolymer, a dipentaerythritol pentaacrylate hexamethylene diisocyanate urethane prepolymer, a pentaerythritol triacrylate toluene diisocyanate urethane prepolymer, a dipentaerythritol pentaacrylate toluene diisocyanate urethane prepolymer, a pentaerythritol triacrylate isophorone diisocyanate urethane prepolymer, a dipentaerythritol pentaacrylate isophorone diisocyanate urethane prepolymer, and the like can be used.

The urethane-based resin preferably has a molecular weight of 1000 to 10000, and more preferably 2000 to 5000. Also, a GPC method can be used as a method for measuring the molecular weight.

Herein, the amount of a urethane-based resin is preferably 5 to 20 parts by weight with respect to 100 parts by weight of a mixture containing a (meth)acrylate compound and a urethane-based resin. The urethane-based resin preferably has a molecular weight of 2000 to 5000, when it is 5 to 20 parts by weight.

2-2. Photopolymerization Initiator

Examples of a polymerization initiator include benzyl methyl ketals such as 2,2-dimethoxy-1,2-diphenylethan-1-one, α-hydroxyl ketones such as 1-hydroxycyclohexyl phenyl ketone and 2-hydroxy-2-methyl-1-phenylpropan-1-one, α-aminoketones such as 2-methyl-1[4-(methylthio)phenyl]-2-morpholinopropan-1-one, and 2-benzyl-2-dimethylamino-1-(4-morpholinophenyl)-1-butanone, bisacylphosphine oxides such as bis(2,6-dimethoxybenzoyl)-2,4,4-trimethylpentyl phosphine oxide, bisimidazoles such as 2,2′-bis(o-chlorophenyl)-4,4′,5,5′-tetraphenyl-1,1′-bisimid azole and bis(2,4,5-triphenyl) imidazole, N-allylglycines such as N-phenylglycine, organic azides such as 4,4′-diazide chalcone, and organic peroxides such as 3,3′,4,4′-tetra(tert-butylperoxycalboxyl)benzophenone as well as compounds cited in J. Photochem. Sci. Technol., 2, 283(1987).

Specific examples thereof include iron arene complexes, trihalogenomethyl-substituted S-triazine, sulfonium salts, diazonium salts, phosphonium salts, selenonium salts, arsonium salts, and iodonium salts. Also, examples of the iodonium salt include compounds cited in Macromolecules, 10, 1307(1977), such as chlorides and bromides of iodonium (e.g., diphenyliodonium, ditolyliodonium, phenyl(p-anisyl)iodonium, bis(m-nitrophenyl)iodonium, bis(p-tert-butylphenyl)iodonium, and bis(p-chlorophenyl)iodonium), fluoroborates, hexafluorophosphates, hexafluoroarsenates, and aromatic sulfonates, and sulfonium organoboron complexes such as diphenylphenacyl sulfonium (n-butyl)triphenylborate.

2-3. Additives

An additive can be mixed in a resin composition for forming a hard coat layer as needed. For example, examples thereof include a silicone-based additive and a fluorine-based additive (for example, a leveling agent) for imparting leveling, a surface slip property, a low water contact angle property, and the like. As a result of adding such an additive, scratch resistance of the surface of the hard coat layer can be increased. Also, if ultraviolet rays are utilized in photopolymerization, bleeding of the above-described additive into an air interface can reduce inhibition of curing of a resin by oxygen. Thus, an effective degree of curing under a low irradiation intensity condition can be obtained. The blending amounts of these additives can be set to 0.01 to 0.5 parts by weight with respect to 100 parts by weight of the resin composition for forming a hard coat layer.

3. Physical Properties of Hard Coat Layer

The hard coat layer has a thickness of 0.25 μm or more and 23 μm or less, and if it is required to have a pencil hardness, the lower limit of the thickness of the hard coat layer preferably is 6 μm or more, and more preferably 8 μm or more. Also, the upper limit thereof is preferably 20 μm or less, and more preferably 14 μm or less. Also, in particular, if bendability is required, the lower limit of the thickness of the hard coat layer is preferably 0.5 μm or more, and more preferably 0.75 μm or less. Also, the upper limit thereof is preferably 1.5 μm or less, and more preferably 1.25 μm or less. This is because, if the thickness of the hard coat layer is less than 0.25 μm, sufficient friction resistance performance cannot be obtained, and from the viewpoint of bendability, it is not preferable that the thickness thereof exceeds 23 μm.

The hard coat layer preferably has a hardness of 480 to 850 N/mm², and more preferably has a hardness of 500 to 800 N/mm² or more, in a Martens hardness test. This is because, if the hardness is smaller than 480 N/mm², the pencil hardness, which will be described next, decreases, and if the hardness is larger than 850 N/mm², bendability decreases. Martens hardness can be measured using the above-described method.

In order to realize a high surface hardness even if the hard coat layer is thin, the Martens hardness of the hard coat layer needs to be equal to the Martens hardness of the base film. From this point of view, a ratio of Martens hardnesses (the Martens hardness of the hard coat/the Martens hardness of the base film) preferably is 0.8 to 3.8, more preferably 0.9 to 3.0, and even more preferably 1.0 to 2.5.

Also, the hard coat layer preferably has a surface pencil hardness of 3H or more in a surface pencil hardness test defined in JIS5600-5-4(1999).

Also, a cover film formed by a film base material and a hard coat layer as described above is such that, after the cover film is bent based on a cylindrical mandrel (JISK5600-5-1), the bent cover film has a cylindrical shape with a diameter of 12 mm or more, and no crack appears in the hard coat layer.

4. Method for Manufacturing Cover Film

Although there is no particular limitation on a method for manufacturing a cover film according to the present invention, for example, a resin composition for forming a hard coat layer is applied to the base film, the resulting film is dried and cured through photopolymerization, and thus a cover film can be obtained.

A known method such as a method employing a roll coater, a reverse roll coater, a gravure coater, a knife coater, or a bar coater can be adopted as a method for applying a resin composition for forming a hard coat layer on a base film.

There is no particular limitation on a method for drying the applied resin composition for forming a hard coat layer. An example thereof is a method by which the base film to which the resin composition for forming a hard coat layer is applied is passed through a dryer. The drying temperature at this time is preferably 40 to 100° C., for example.

Also, when this coating film is cured, ultraviolet rays are preferably used as an ionizing radiation source, and a light source such as a high pressure mercury lamp, a low pressure mercury lamp, an ultra high pressure mercury lamp, a metal halide lamp, a carbon arc, and a xenon arc can be utilized.

5. Cutting Cover Film (Trimming)

The cover film manufactured as described above is cut to a desired size and then used. Although the cover film can be cut using a laser or a cutting machine, the inventor of the present invention found that, if the line roughness of an end surface of the hard coat layer resulting from cutting is large, the above-described bending performance (bending resistance) is affected.

From this point of view, the end surface of the hard coat layer that has been cut in the above-described manner preferably has an arithmetic average roughness Ra of 2.5 μm or less, more preferably 2.0 μm or less, and particularly preferably 1.5 μm or less.

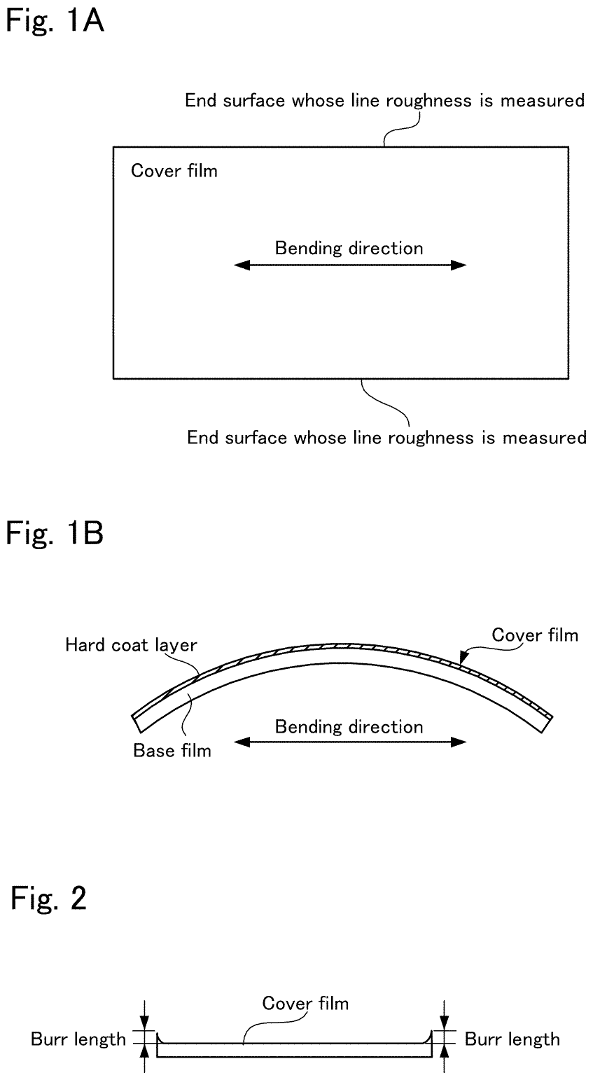

Also, as shown in FIG. 1, the line roughness Ra of the end surface refers to at least a line roughness of the end surface extending along a direction in which the cover film is bent (bending direction). Note that the bending direction usually refers to a long-side direction of the cover film in many cases, but may refer to a short-side direction. If the cover film is bent in both the long-side direction and the short-side direction, the direction in which the cover film is bent more is referred to as the bending direction. From this point of view, it is more preferable that an end surface extending in a direction orthogonal to the bending direction also has a line roughness Ra as described above. The line roughness Ra can be measured as described below, for example.

That is, an objective lens of a laser microscope is set to have a magnification of 150, and the end surface of the cut hard coat layer (the end surface that is parallel to the bending direction) is observed. At this time, the line roughness Ra is measured at five different points (five points at approximately equal intervals) under a condition where the measurement length is 70 μm or more, and an average thereof is calculated. Note that, although it is preferable to calculate an average of the line roughnesses Ra at five points, for example, if it is difficult to make measurements, an average of the line roughnesses Ra at fewer than five points can be calculated, or the number of measurement points can also be set to one.

Note that, in order to reduce the line roughness Ra of the end surface of the hard coat layer, it is preferable to perform cutting using a laser. Also, if the line roughness Ra is small, burrs that appear at an end portion of the cover film can be reduced. Note that the cutting speed of the laser is not particularly limited, but can be set to 50 to 600 mm/sec, for example.

Also, if cutting is performed using a laser, it is preferable to perform cutting after a protective sheet is attached to the hard coat layer, in order to protect the hard coat layer from smoke generated during cutting. A sheet obtained by applying an adhesive layer to a base material made of a resin material such as PET can be used as the protective sheet, for example. The adhesive layer is attached to the hard coat layer, and then cut using a laser.

6. Characteristics With a cover film according to the present embodiment, by setting a line roughness Ra of an end surface of a hard coat layer to 2.5 μm or less, bending performance can be improved. Thus, this cover film can be suitably used as a cover film for a bending display.

### WORKING EXAMPLES

Next, working examples of the present invention will be described below. However, the present invention is not limited to the working examples below.

### 1. Production of Working Examples and Comparative Examples

Hereinafter, production of cover films according to Working Examples 1 to 6 and Comparative Examples 1 to 6 will be described.

First, a PET film (U48 manufactured by TORAY INDUSTRIES, Inc.) having a thickness of 100 μm was prepared as a base film. Next, a hard coat paint (beamset 907 manufactured by ARAKAWA CHEMICAL INDUSTRIES, LTD.) containing a (meth)acrylate compound was prepared as a resin composition for forming a hard coat layer. Then, this resin composition for forming a hard coat layer was applied to one side of the base film using a wire bar coater. After a diluted solvent was dried through heat treatment at 80° C. for 2 to 5 minutes, the resin composition for forming a hard coat layer was cured using a UV irradiation apparatus (manufactured by Heraeus) with the cumulative amount of light being 200 mJ/cm² to form a hard coat layer. The hard coat layer had a thickness of 12 μm.

### 2. Bending Resistance Evaluation Test

A sample piece having a size of 2.5×10 cm and a sample piece having a size of 5×10 cm were cut out from each of the working examples and the comparative examples that were produced in the above-described manner, using a laser cutting apparatus (SpiritGX 30W manufactured by GCC Co., Ltd.) with conditions such as speed changed. The protective sheet was a PET film in which adhesive layers that each had a thickness of 5 μm were stacked on each other and that had a thickness of 100 μm, and an adhesive layer was attached to the hard coat layer.

Also, while the output of the laser was 30W, the sample pieces were cut out at 50% of 30W. Also, the cutting speed of the laser was adjusted to 5 to 15% where the speed is 2 m/sec at 100%, and the sample pieces were cut out.

Also, sample pieces were prepared as comparative examples through cutting using a cutting machine.

Then, a line roughness Ra of the hard coat layer of an end surface extending along a long side of the cutout sample piece was measured. The measurement method was the same as described in the above-described embodiment. Also, the length of a burr of an end surface extending along a long side of the sample piece was measured. A burr refers to the length shown in FIG. 2. Note that the thickness of the end portion on the long side of the sample at the center in the long-side direction and the thickness of the sample at the center were measured, and a difference therebetween was regarded as the burr length. Note that, although a measurement was made for the pair of long sides, the longer value was adopted as the measurement value.

Next, after the sample pieces that were prepared as described above were each bent along the long sides based on a cylindrical mandrel (JISK5600-5-1), whether or not a crack appeared in the hard coat layers was visually observed. The diameter of each of the cylinders used was in a range of 12 mm to 22 mm, and a test was performed every 2 mm. At this time, a measurement was made for the cylinders along a surface of the base film on which the hard coat layer was not formed. The maximum diameter of a cylinder on which no crack appeared was used as a test result. The results are shown in Table 1 below.

TABLE 1

| | | | | | Average of | | | |
|---|---|---|---|---|---|---|---|---|
| | | | Size of | | Line Roughness | | | |
| | | Laser | Sample | | Ra of End | | | Mandrel |
| | Cutting Method | Conditions | Pieces | | Surface | Burr | | Test |
| Work. Ex. 1 | Laser | Speed 5% | 2.5 × 10 | cm | 1.80 μm | 8 | μm | 12 mm |
| Work. Ex. 2 | Laser | Speed 10% | 2.5 × 10 | cm | 1.40 μm | 2 | μm | 12 mm |
| Work. Ex. 3 | Laser | Speed 15% | 2.5 × 10 | cm | 1.15 μm | 0 | μm | 12 mm |
| Work. Ex. 4 | Laser | Speed 5% | 5 × 10 | cm | 1.92 μm | 8 | μm | 14 mm |
| Work. Ex. 5 | Laser | Speed 10% | 5 × 10 | cm | 1.55 μm | 2 | μm | 14 mm |
| Work. Ex. 6 | Laser | Speed 15% | 5 × 10 | cm | 1.41 μm | 0 | μm | 14 mm |
| Comp. Ex. 1 | Laser | Speed 0.5% | 2.5 × 10 | cm | 6.24 μm | 22 | μm | 20 mm |
| Comp. Ex. 2 | Laser | Speed 2% | 2.5 × 10 | cm | 2.94 μm | 15 | μm | 20 mm |
| Comp. Ex. 3 | Cutting Machine | — | 2.5 × 10 | cm | 2.90 μm | 0 | μm | 20 mm |
| Comp. Ex. 4 | Laser | Speed 0.5% | 5 × 10 | cm | 7.79 μm | 22 | μm | 22 mm |
| Comp. Ex. 5 | Laser | Speed 2% | 5 × 10 | cm | 3.34 μm | 15 | μm | 22 mm |
| Comp. Ex. 6 | Cutting Machine | — | 5 × 10 | cm | 3.46 μm | 0 | μm | 22 mm |

### 3. Martens Hardness and Pencil Hardness Evaluation Test

A surface pencil hardness test conforming to JIS-K5600-5-4 was performed on the hard coat layers of Working Examples 1 to 6 and Comparative Examples 1 to 6 above. That is, a test was performed using pencils with a hardness of 2H to 5H (Mitsubishi Pencil Co., Ltd.) in order with a load of 750 g applied to the surface of the hard coat layer. Then, a change in the appearance of the surface of the hard coat layer due to a scratch was visually evaluated. The results were all 4H.

Also, the hard coat layers according to Working Examples 1 to 6 and Comparative Examples 1 to 6 each had a Martens hardness of 770 N/m². This Martens hardness was measured after the hard coat layer was formed as described above by applying the resin composition for forming a hard coat layer on a glass plate.

### 4. Discussion

As described above, in the bending resistance evaluation test, with regard to Comparative Examples 1 to 6 in which the line roughness of the end surface was larger than 2.5 μm, the maximum diameters of cylinders in which no crack appeared were larger than those of Working Examples 1 to 6. Thus, it was found that if the line roughness of the end surface of a sample piece is large, the bending performance deteriorates. This trend is the same as in a case where the size of a sample piece is changed, and if the line roughness of an end surface is larger than 2.5 μm, the bending performance deteriorates. However, it was found that, if the size of a sample piece is increased, the bending performance slightly decreases for both working examples and comparative examples. Also, it was found that, if the line roughness of the end surface is small, burrs that appear at the end portion are also reduced. As described above, it was found that the cover films according to the working examples can be suitably used for a bending display having a curved surface with a small radius of curvature.

What is claimed is:

1. A cover film for a bending display, comprising:
a transparent base film; and
a hard coat layer formed on at least one surface of the transparent base film,
wherein the hard coat layer has a thickness of 23 μm or less, and
an end surface of the hard coat layer has a line roughness Ra of 2.5 μm or less.

2. The cover film according to claim 1,
wherein the end surface is cut using a laser.

3. The cover film according to claim 1,
wherein the cover film has a surface pencil hardness of 3H or more.

4. A method for manufacturing a cover film, comprising:
forming a cover film by stacking a hard coat layer having a thickness of 23 μm or less on a transparent base film;
disposing a protective film on the hard coat layer; and
cutting the cover film using a laser,
wherein an end surface of the hard coat layer has a line roughness Ra of 2.5 μm or less.

5. The method for manufacturing a cover film according to claim 4,
wherein the laser has a cutting speed of 50 to 600 mm/sec.
